(19) United States
(12) Patent Application Publication
(10) Pub. No.: US 2007/0092021 A1
(43) Pub. Date: Apr. 26, 2007

(54) QUADRATURE MODULATOR AND VECTOR CORRECTION METHOD

(75) Inventors: Shoji OTAKA, Kanagawa-ken (JP); Toru Hashimoto, Kanagawa-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/537,262

(22) Filed: Sep. 29, 2006

(30) Foreign Application Priority Data
Sep. 30, 2005 (JP) P2005-287517

(51) Int. Cl. H04L 27/02; H04L 27/12; H03D 3/00

(52) U.S. Cl. 375/268; 375/302; 375/322

(57) ABSTRACT

A quadrature modulator for generating a transmission signal includes an orthogonal signal generator configured to generate a first local signal and a second local signal orthogonal to the first local signal, a mix-adder configured to generate a first RF signal based on a first baseband signal, the first local signal, and the second local signal, and a mix-subtracter configured to generate a second RF signal based on a second baseband signal, the first local signal, and the second local signal. The quadrature modulator also includes an output subtracter configured to determine a difference between the first RF signal and the second RF signal and to generate the transmission signal based on the difference; and an amplitude adjuster configured to adjust an amplitude of the first baseband signal before feeding it to the mix-adder or adjust an amplitude of the second baseband signal before feeding it to the mix-subtracter.

### CROSS REFERENCE TO RELATED APPLICATIONS

This application is based upon and claims a benefit of priority from prior Japanese Patent Application 2005-287517 filed on Sep. 30, 2005 the entire contents of which are incorporated by reference herein.

### BACKGROUND OF THE INVENTION

1. Field of the Invention

Exemplary embodiments of the invention relate to a quadrature modulator.

2. Discussion of the Background

A quadrature modulation technique is used for radio communication. A signal transmitted using this technique is a vector signal that includes an in-phase signal (I_{sig}) and a quadrature signal (Q_{sig}). A quadrature modulator (QMOD), which includes a local oscillator and a phase shifter (PS), generates the I_{sig} and the Q_{sig}.

It may be advantageous for a vector error of a QMOD transmitted signal to be reduced as far as possible. A vector error in a transmitter unit is caused by factors such as a phase noise in a synthesizer, distortion in the power amplifier, and relative errors of amplitude and phase between I_{sig} and Q_{sig}. Those factors relate to production tolerances of an integrated circuit (IC) including the QMOD circuit.

Recently, for correcting such errors, correction circuits have been built in an IC. Koullias describes a kind of such correction circuits (see, I. A. Koullias, et. al, “A 900 MHz Transceiver Chip Set for Dual-Mode Cellular Radio Mobile Terminals”, 1993 ISSCC Technical digest, pp. 140-141). Koullias indicates that I_{sig} and Q_{sig} may each pass through amplitude restrictors after correction. However, amplitude and phase errors between I_{sig} and Q_{sig} may result from variations in characteristics of the restrictors through which the I_{sig} and Q_{sig} signals pass. For example, restrictor production tolerances may result in characteristic variations between the restrictors used for each of I_{sig} and Q_{sig}.

### SUMMARY OF THE INVENTION

Accordingly, one object of this invention is to provide a novel quadrature modulator for generating a transmission signal, the quadrature modulator comprising: an orthogonal signal generator configured to generate a first local signal and a second local signal orthogonal to the first local signal; a mix-adder configured to generate a first RF signal based on a first baseband signal, the first local signal, and the second local signal; a mix-subtracter configured to generate a second RF signal based on a second baseband signal, the first local signal, and the second local signal; an output subtracter configured to determine a difference between the first RF signal and the second RF signal and generate the transmission signal based on the difference; and an amplitude adjuster configured to adjust an amplitude of the first baseband signal before feeding the first baseband signal to the mix-adder or adjust an amplitude of the second baseband signal before feeding the second baseband signal to the mix-subtracter.

Another object of this invention is to provide a novel radio communicator comprising: a local oscillator configured to generate a source local signal; a transmission signal processor configured to generate a first baseband signal and a second baseband signal; an orthogonal signal generator configured to generate a first local signal and a second local signal from the source local signal, the second local signal being orthogonal to the first local signal; a mix-adder configured to generate a first RF signal based on the first baseband signal, the first local signal, and the second local signal; a mix-subtracter configured to generate a second RF signal based on the second baseband signal, the first local signal, and the second local signal; an output subtracter configured to determine a difference between the first RF signal and the second RF signal and to generate the transmission signal based on the difference; and an amplitude adjuster configured to adjust an amplitude of the first baseband signal before feeding the first baseband signal to the mix-adder, or adjust an amplitude of the second baseband signal before feeding the second baseband signal to the mix-subtracter.

Another object of this invention is to provide a novel vector correction method for canceling an amplitude difference in a transmission signal, the method comprising steps of: generating a source local signal; generating a first baseband signal and a second baseband signal; generating a first local signal and a second local signal from the source local signal, the second local signal being orthogonal to the first local signal; generating, in a mix-adder, a first RF signal based on the first baseband signal, the first local signal, and the second local signal; generating, in a mix-subtracter, a second RF signal based on the second baseband signal, the first local signal, and the second local signal; subtracting one of the first RF signal or the second RF signal from the other to generate the transmission signal; demodulating the first baseband signal and the second baseband signal from the transmission signal; configuring one of the mix-adder and the mix-subtracter as a halted mixer having a halted operation and the other one of the mix-adder and the mix-subtracter as an operating mixer; providing the first baseband signal to the operating mixer and storing components of the first baseband signal and the second baseband signal as first storing data; reconfiguring the halted mixer as a newly operating mixer and the operating mixer as a newly halted mixer, and providing the second baseband signal to the newly operating mixer and storing components of the first baseband signal and the second baseband signal as second storing data; and adjusting the amplitude adjuster to cancel the amplitude difference between the components represented by the first storing data and the second storing data.

### BRIEF DESCRIPTION OF THE DRAWINGS

Referring now to the drawings, wherein like reference numerals designate identical or corresponding parts throughout the several views.

The invention and attendant advantages therefore are best understood from the following description of the non-limiting embodiments when read in connection with the accompanying Figures, wherein:

FIG. 1 is a vector diagram illustrating a concept of correction at a QMOD according to an embodiment of the invention;

FIG. 2 is a block diagram of a first non-limiting embodiment of a QMOD;

FIG. 3 is a block diagram of a second non-limiting embodiment of a QMOD;

FIG. 4 is a circuit diagram of a part of the embodiment shown in FIG. 3;

FIG. 5 is a block diagram of a third non-limiting embodiment of a QMOD;

FIG. 6 is a circuit diagram of a non-limiting embodiment of a LO_{I}-restrictor of the QMOD;

FIG. 7 is a block diagram of a non-limiting embodiment of a radio communicator;

FIG. 8 is a circuit diagram of a non-limiting embodiment of a reference current generator;

FIG. 9 is a flowchart of an embodiment of a method for adjusting the relative amplitude between I_{sig} and Q_{sig};

FIG. 10 is a circuit diagram of a portion of the embodiment shown in FIG. 3 in a first situation;

FIG. 11 is a circuit diagram of a portion of the embodiment shown in FIG. 3 in a second situation;

FIG. 12 is a circuit diagram of a portion of the embodiment shown in FIG. 3 in a third situation; and

FIG. 13 is a circuit diagram of a portion of the embodiment shown in FIG. 3 in a fourth situation.

### DESCRIPTION OF THE PREFERRED EMBODIMENTS

Referring now to the Figures in which like reference numerals designate identical or corresponding parts throughout the several views.

(Concept)

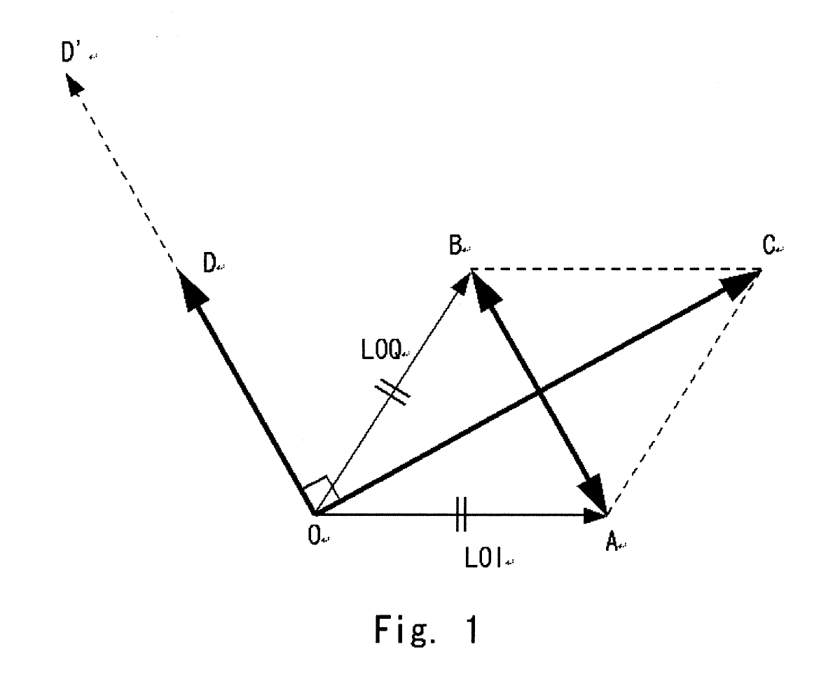

FIG. 1 is a vector diagram illustrating a concept of correction at a QMOD according to an embodiment of the invention. A vector OA represents signal LO_{I} that is an in-phase component of a Local Signal (LO) (not shown). A vector OB represents signal LO_{Q} that is a quadrature component of LO. Preferably, a phase difference between LO_{I} and LO_{Q} should be 90 degrees, and LO_{I} and LO_{Q} should have the same amplitude. However FIG. 1 illustrates an example in which the phase difference between LO_{I} and LO_{Q} is not 90 degrees. Such a phase difference may result from a phase error of LO caused in a phase shifter (PS) of a QMOD.

In this example, as the amplitudes of the LO_{I} and the LO_{Q} are the same, a vector OC, which is a composition vector of OA and OB, is orthogonal to a vector OD that is a composition vector of −OA and OB. However, the amplitudes of OC and OD are not the same because of the phase error between the OA and the OB.

To correct such an error according to the phase error of the LO, at least one amplitude of an in-phase base band signal (I_{sig}) and a quadrature base band signal (Q_{sig}) may be multiplied by a certain coefficient, I_{sig} may be multiplied by the OC, and Q_{sig} may be multiplied by the OD.

A so-called ideal output S(t) of a QMOD is defined as:
S(t)=I_{sig} cos(ω_{c}t)−Q_{sig} sin(ω_{c}t) (1)

where ω_{c} is an angular frequency of the Local Signal (LO), the cos(ω_{c}t) corresponds to the OC, and the sin(ω_{c}t) corresponds to the OD.

An actual (i.e., non-ideal) output S₁(t) of the QMOD has an amplitude error between the OC and the OD indicated as a coefficient A.
S₁(t)=I_{sig} cos(ω_{c}t)−Q_{sig}A sin(ω_{c}t) (2)

To cancel the amplitude error A, a coefficient K may be introduced. The value of K may be set to satisfy the equation AK=1 (i.e., K=1/A). Thus, Q_{sig} is multiplied by K.

$$\begin{matrix}{S}_{2} ( t ) = {I}_{sig} cos ( {ω}_{c} t ) - {KQ}_{sig} A sin ( {ω}_{c} t ) \\ = {I}_{sig} cos ( {ω}_{c} t ) - 1 {Q}_{sig} sin ( {ω}_{c} t ) \\ = S ( t )\end{matrix} \qquad ( 3 )$$

According to equation (3), correcting the amplitude of at least one of I_{sig} or Q_{sig} is equivalent to correcting the amplitude error between OC and OD. That is, correcting the amplitude of at least one of I_{sig} or Q_{sig} is equivalent to correcting the phase error between LO_{I} and LO_{Q} if the amplitudes of LO_{I} and LO_{Q} are the same. In FIG. 1, the vector D′ represents vector OD multiplied by the K. (First embodiment)

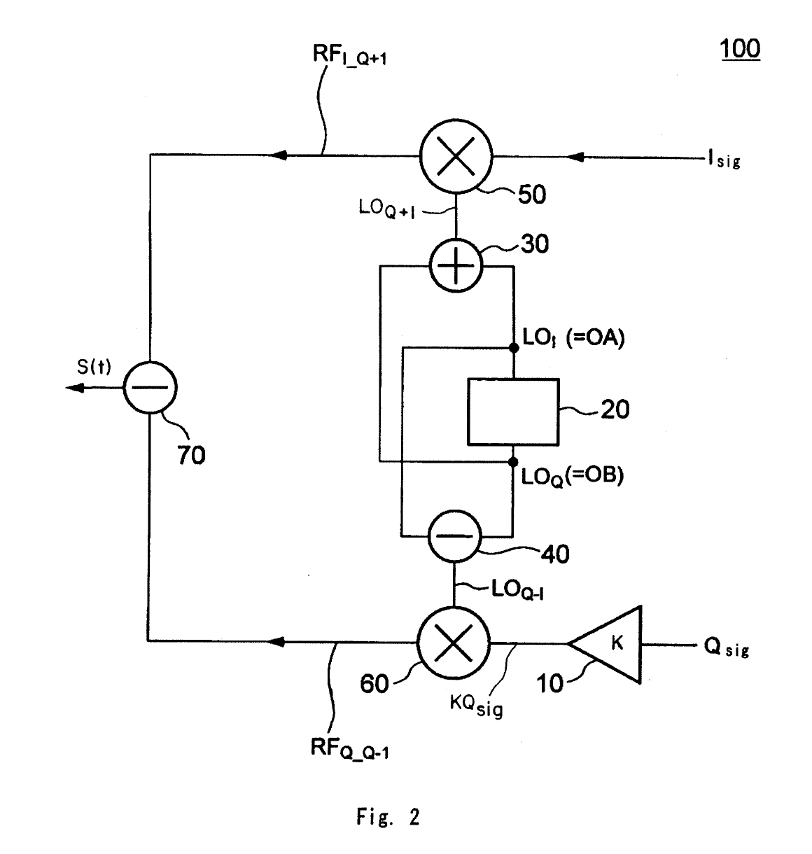

FIG. 2 is a block diagram of a first non-limiting embodiment of a QMOD that provides for adjustment in the relative amplitude between I_{sig} and Q_{sig}.

QMOD 100 includes a variable gain amplifier (VGA) 10, a PS 20, an adder 30, a subtracter 40, an I_{ch}-mixer 50, a Q_{ch}-mixer 60, and a subtracter 70.

An input of the VGA 10 is Q_{sig}. The VGA 10 multiplies Q_{sig} by the coefficient K for correcting the relative amplitude error, and outputs a result of the multiplication KQ_{sig}.

The PS 20 generates the LO_{I} and the LO_{Q}. The LO_{I} and the LO_{Q} preferably have a relative phase difference of 90 degrees. However, LO_{I} and the LO_{Q} may have an error as described above.

The adder 30 adds LO_{I} and LO_{Q}, and outputs the result LO_{Q+I}. LO_{Q+I} corresponds to the vector OC in FIG. 1. The subtracter 40 subtracts LO_{I} from LO_{Q}, and outputs the result LO_{Q-I}. LO_{Q-I} corresponds to the vector OD in FIG. 1. The I_{ch}-mixer 50 is a mixer for mixing I_{sig} with LO_{Q+I}, and outputs the result of the mixing RF_{I}_{_{—}}_{Q+I}.

The Q_{ch}-mixer 60 mixes KQ_{sig} with LO_{Q-I}, and outputs the result of the mixing RF_{Q}_{_{—}}_{Q-I}.

The subtracter 70 subtracts the RF_{Q}_{_{—}}_{Q-I} from the RF_{I}_{_{—}}_{Q+I} to generate a modulated signal S(t).

In this embodiment, the VGA 10 processes the amplitude error correction. The K may be LO_{Q+I}/LO_{Q-I}.

A VGA other than VGA 10 may be used to multiply the I_{sig} by LO_{Q-I}/LO_{Q+I}, which may be a reciprocal of K, and to output a result of the multiplication.

### Second Embodiment

Accordingly the cos(ω_{c}t) corresponds to the OC and the sin(ω_{c}t) corresponds to the OD. Thus, equation (3) can be transformed as below.

$$\begin{matrix}{S}_{2} ( t ) = {I}_{sig} cos ( {ω}_{c} t ) - {KQ}_{sig} A sin ( {ω}_{c} t ) \\ = {I}_{sig} ( OA + OB ) - {KQ}_{sig} ( - OA + OB ) \\ = {I}_{sig} OA + {I}_{sig} OB - {KQ}_{sig} ( - OA ) - {KQ}_{sig} OB \\ = {I}_{sig} {LO}_{I} + {I}_{sig} {LO}_{Q} - ( - {KQ}_{sig} {LO}_{I} + {KQ}_{sig} {LO}_{Q} )\end{matrix} \qquad ( 4 )$$

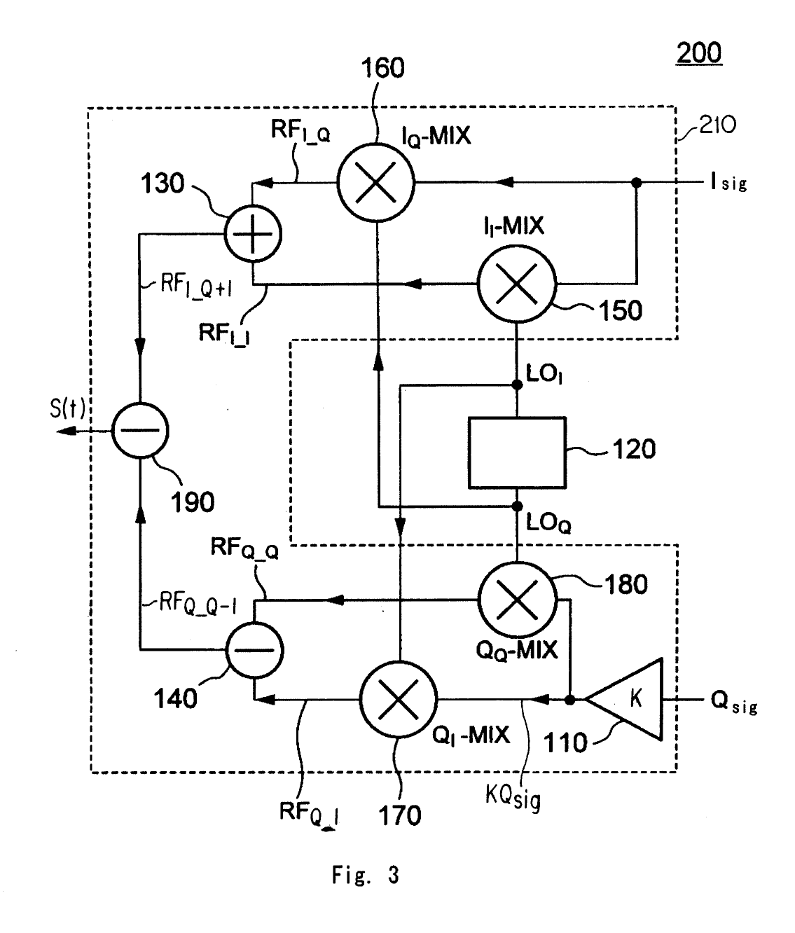

FIG. 3 illustrates a diagram of an example of a second non-limiting embodiment of a QMOD 200 based on equation (4).

QMOD 200 includes a VGA 110, a PS 120, an adder 130, a subtracter 140, an I_{I}-mixer 150, an I_{Q}-mixer 160, a Q_{I}-mixer 170, a Q_{Q}-mixer 180, and a subtracter 190.

An input of VGA 110 is Q_{sig}. VGA 110 multiplies Q_{sig} by the coefficient K for correcting the relative amplitude error, and outputs a result of the multiplication KQ_{sig}.

The PS 120 generates LO_{I} and LO_{Q}.

The I_{I}-mixer 150 is a mixer for mixing I_{sig} with LO_{I}, and outputs the result of the mixing RF_{I}_{_{—}}_{I}.

The I_{Q}-mixer 160 is a mixer for mixing I_{sig} with LO_{Q}, and outputs the result of the mixing RF_{I}_{_{—}}_{Q}.

The Q_{I}-mixer 170 is a mixer for mixing LO_{I} with KQ_{sig} output from the VGA 110, and outputs the result of the mixing RF_{Q}_{_{—}}_{I}.

The Q_{Q}-mixer 180 is a mixer for mixing LO_{Q} with KQ_{sig} output from the VGA 110, and outputs the result of the mixing RF_{Q}_{_{—}}_{Q}.

The adder 130 adds RF_{I}_{_{—}}_{I} and RF_{I}_{_{—}}_{Q}, and outputs the result RF_{I}_{_{—}}_{Q+I} that corresponds to “I_{sig} LO_{I}+I_{sig} LO_{Q}”.

The subtracter 140 subtracts the RF_{Q}_{_{—}}_{I} from the RF_{Q}_{_{—}}_{Q}, and outputs the result RF_{Q}_{_{—}}_{Q-I} that corresponds to “−K Q_{sig} LO_{I}+K Q_{sig} LO_{Q}”.

The subtracter 190 subtracts the RF_{Q}_{_{—}}_{Q-I} from the RF_{I}_{_{—}}_{Q+I} to generate a modulated signal S(t).

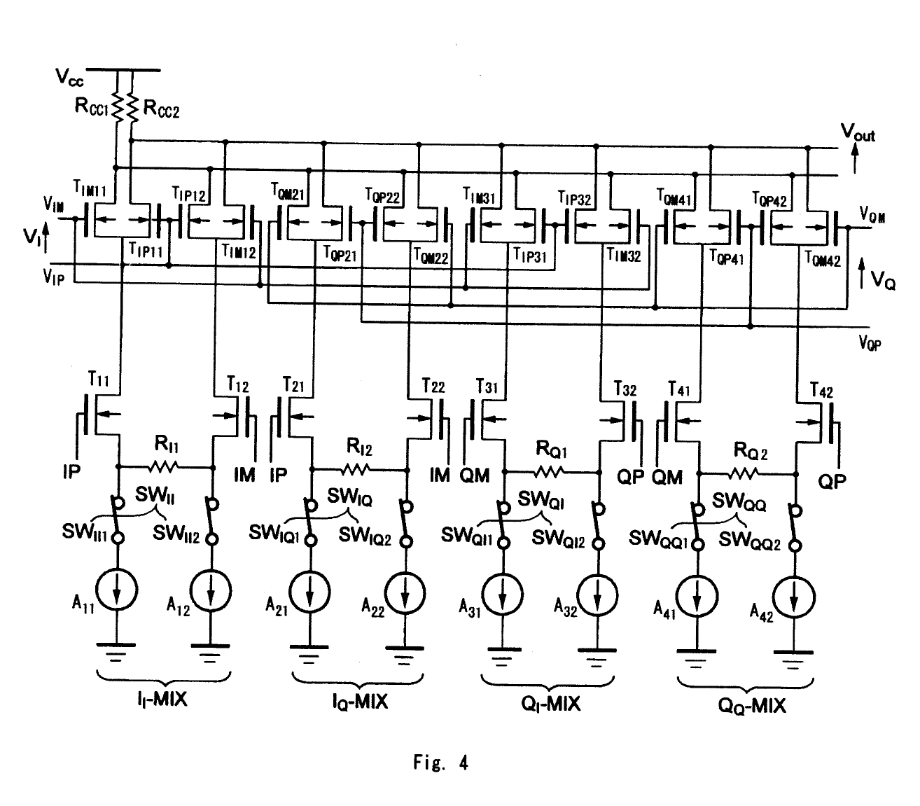

FIG. 4 is a circuit diagram of an example of a part 210 in a broken line frame of the FIG. 3.

In FIG. 4, V_{OUT} corresponds to the S(t), V_{I} corresponds to OA, and V_{Q} corresponds to OB. V_{IP} and V_{IM} represent V_{I} as a differential signal pair, and V_{QP} and V_{QM} represent V_{Q} as a differential signal pair.

I_{P} and I_{M} represent I_{sig} as a differential signal pair. Iₚ represents a positive input, and I_{M} represents a negative input. Q_{P} and Q_{M} represent Q_{sig} as a differential signal pair. Q_{P} represents a positive input, and Q_{M} represents a negative input.

The I_{I}-mixer I_{I}-MIX includes transistors T_{IM11}, T_{IP11}, T_{IP12}, T_{IM12}, T₁₁, T₁₂, a pair of switches SW_{I1}, a pair of current sources, and a resistor R_{I1}. Current from a drain of T_{IM11} flows into a V_{cc} line through a resistor R_{CC1}. A gate of T_{IM11} receives V_{IM}. Current from a drain of T_{IP11} flows into the V_{cc} line through a resistor R_{CC2}. A gate of T_{IP11} receives V_{IP}. The drain of T₁₁ connects to sources of T_{IM11} and T_{IP11}. Iₚ is input to a gate of T₁₁. Current from a drain of T_{IP12} flows into the V_{cc} line through the resistor R_{CC1}. A gate of T_{IP12} receives V_{IP}. Current from a drain of T_{IM12} flows into the V_{cc} line through the resistor R_{CC2}. A gate of T_{IM12} receives V_{IM}. The drain of T₁₂ connects to sources of T_{IP12} and T_{IM12}. I_{M} is input to a gate of T₁₂. The pair of switches SW_{I1} includes switches SW_{I11} and SW_{I12}. An end of SW_{I11} connects to a source of T₁₁. An end of SW_{I12} connects to a source of T₁₂. The pair of current sources includes current sources A₁₁ and A₁₂. Each of A₁₁ and A₁₂ has one end that is grounded. The other end of A₁₁ connects to the other end of the SW₁₁₁. The other end of A₁₂ connects to the other end of SW_{I12}. R_{I1} connects to the sources of T₁₁ and T₁₂.

The I_{Q}-mixer I_{Q}-MIX includes transistors T_{QM21}, T_{QP21}, T_{QP22}, T_{QM22}, T₂₁, T₂₂, a pair of switches SW_{IQ}, a pair of current sources, and a resistor R₁₂. Current from a drain of T_{QM21} flows into the V_{cc} line through the resistor R_{CC1}. A gate of T_{QM2}, receives V_{QM}. Current from a drain of T_{QP21} flows into the V_{cc} line through the resistor R_{CC2}. A gate of T_{QP21} receives V_{QP}. The drain of T₂₁ connects to sources of T_{QM21} and T_{QP21}. I_{P} is input to a gate of T₂₁. Current from a drain of T_{QP22} flows into the V_{cc} line through the resistor R_{CC1}. A gate of T_{QP22} receives V_{QP}. Current from a drain of T_{QM22} flows into the V_{cc} line through the resistor R_{CC2}. A gate of T_{QM22} receives V_{QM}. The drain of T₂₂ connects to sources of T_{QP22} and T_{QM22}. I_{M} is input to a gate of T₂₂. The pair of switches SW_{IQ} includes switches SW_{IQ1} and SW_{IQ2}. An end of SW_{IQ1} connects to a source of T₂₁. An end of SW_{IQ2} connects to a source of T₂₂. The pair of current sources includes current sources A₂₁ and A₂₂. Each of A₂₁ and A₂₂ has one that is grounded. The other end of A₂₁ connects to the other end of SW_{IQ1}. The other end of A₂₂ connects to the other end of SW_{IQ2}. R₁₂ connects to the sources of T₂₁ and T₂₂. R_{I2} may have a same resistance as R_{I1}.

The Q_{I}-mixer Q_{I}-MIX includes transistors T_{IM31}, T_{IP31}, T_{IP32}, T_{IM32}, T₃₁, T₃₂, a pair of switches SW_{Q1}, a pair of current sources, and a resistor R_{Q1}. Current from a drain of T_{IM31} flows into the V_{cc} line through the resistor R_{CC1}. A gate of T_{IM31} receives V_{IM}. Current from a drain of T_{IP31} flows into the V_{cc} line through the resistor R_{CC2}. A gate of T_{IP3}, receives V_{IP}. The drain of T₃₁ connects to sources of T_{IM31} and T_{IP31}. Q_{M} is input to a gate of T₃₁. Current from a drain of T_{IP32} flows into the V_{cc} line through the resistor R_{CC1}. A gate of T_{IP32} receives V_{IP}. Current from a drain of T_{IM32} flows into the V_{cc} line through the resistor R_{CC2}. A gate of T_{IM32} receives V_{IM}. The drain of T₃₂ connects to sources of T_{IP32} and T_{IM32}. Q_{P} is input to a gate of T₃₂. The pair of switches SW_{QI} includes switches SW_{QI1} and SW_{QI2}. An end of SW_{QI1} connects to a source of T₃₁. An end of SW_{QI2} connects to a source of T₃₂. The pair of current sources includes current sources A₃₁ and A₃₂. Each of A₃₁ and A₃₂ has one end that is grounded. The other end of A₃₁ connects to the other end of SW_{QI1}. The other end of A₃₂ connects to the other end of SW_{QI2}. R_{Q1} connects to the sources of T₃₁ and T₃₂.

The Q_{Q}-mixer Q_{Q}-MIX includes transistors T_{QM41}, T_{QP41}, T_{QP42}, T_{QM42}, T₄₁, T₄₂, a pair of switches SW_{QQ}, a pair of current sources, and a resistor R_{Q2}. Current from a drain of T_{QM41} flows into the V_{cc} line through the resistor R_{CC1}. A gate of T_{QM41} receives V_{QM}. Current from a drain of T_{QP41} flows into the V_{cc} line through the resistor R_{CC2}. A gate of T_{QP41} receives V_{QP}. The drain of T₄₁ connects to sources of T_{QM41} and T_{QP41}. Q_{M} is input to a gate of T₄₁. Current from a drain of T_{QP42} flows into the V_{cc} line through the resistor R_{CC1}. A gate of T_{QP42} receives V_{QP}. Current from a drain of T_{QM42} flows into the V_{cc} line through the resistor R_{CC2}. A gate of T_{QM42} receives V_{QM}. The drain of T₄₂ connects to sources of T_{QP42} and T_{QM42}. Q_{P} is input to a gate of T₄₂. The pair of switches SW_{QQ} includes switches SW_{QQ1} and SW_{QQ2}. An end of SW_{QQ1} connects to a source of T₄₁. An end of SW_{QQ2} connects to a source of T₄₂. The pair of current sources includes current sources A₄₁ and A₄₂. Each of A₄₁ and A₄₂ has one end that is grounded. The other end of A₄₁ connects to the other end of SW_{QQ1}. The other end of A₄₂ connects to the other end of SW_{QQ2}. R_{Q2} connects to sources of T₄, and T₄₂. R_{Q2} may have a same resistance as R_{Q1}.

### Third Embodiment

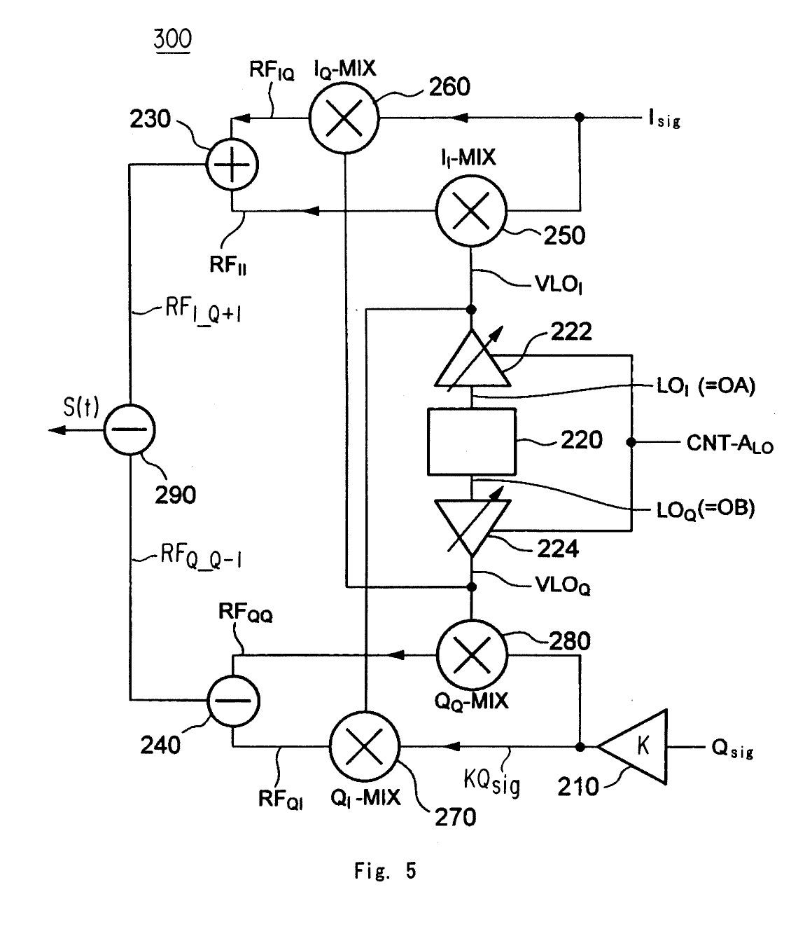

FIG. 5 is a block diagram of a third non-limiting embodiment of a QMOD 300 that provides for adjustment of the relative amplitude between LO_{I} and LO_{Q} to correct amplitude differences that may result from component production tolerances.

QMOD 300 includes a VGA 210, a PS 220, a LO_{I}-restrictor 222, a LO_{Q}-restrictor 224, an adder 230, a subtracter 240, an I_{I}-mixer 250, an I_{Q}-mixer 260, a Q_{I}-mixer 270, a Q_{Q}-mixer 280, and a subtracter 290.

An input of VGA 210 is Q_{sig}. VGA 210 multiplies Q_{sig} by coefficient K for correcting the relative amplitude error, and outputs a result of the multiplication KQ_{sig}.

PS 120 generates LO_{I} and LO_{Q}.

LO_{I}-restrictor 222 restricts the amplitude of LO_{I}, and outputs VLO_{I} as the restricted LO_{I}. LO_{I}-restrictor 222 may be a variable gain amplifier, a variable resistor, or selectable fixed resistors.

LO_{Q}-restrictor 224 restricts the amplitude of LO_{Q}, and outputs VLO_{Q} as the restricted LO_{Q}. LO_{Q}-restrictor 224 may be a variable gain amplifier, a variable resistor, or selectable fixed resistors.

The I_{I}-mixer 250 is a mixer for mixing I_{sig} with VLO_{I} and outputs the result of the mixing RF_{II}.

I_{Q}-mixer 260 is a mixer for mixing I_{sig} with VLO_{Q} and outputs the result of the mixing RF_{IQ}.

Q_{I}-mixer 270 is a mixer for mixing VLO_{I} with KQ_{sig} output from VGA 210 and outputs the result of the mixing RF_{QI}.

Q_{Q}-mixer 280 is a mixer for mixing VLO_{Q} with KQ_{sig} output from VGA 210 and outputs the result of the mixing RF_{QQ}.

Adder 230 adds RF_{II} and RF_{IQ} and outputs the result RF_{I}_{_{—}}_{Q+I} that corresponds to “I_{sig} LO_{I}+I_{sig} LO_{Q}”.

Subtracter 240 subtracts RF_{QI} from RF_{QQ} and outputs the result RF_{Q}_{_{—}}_{Q-I} that corresponds to “−K Q_{sig} LO_{I}+K Q_{sig} LO_{Q}”.

Subtracter 290 subtracts RF_{Q}_{_{—}}_{Q-I} from RF_{I}_{_{—}}_{Q+I} to generate a modulated signal S(t).

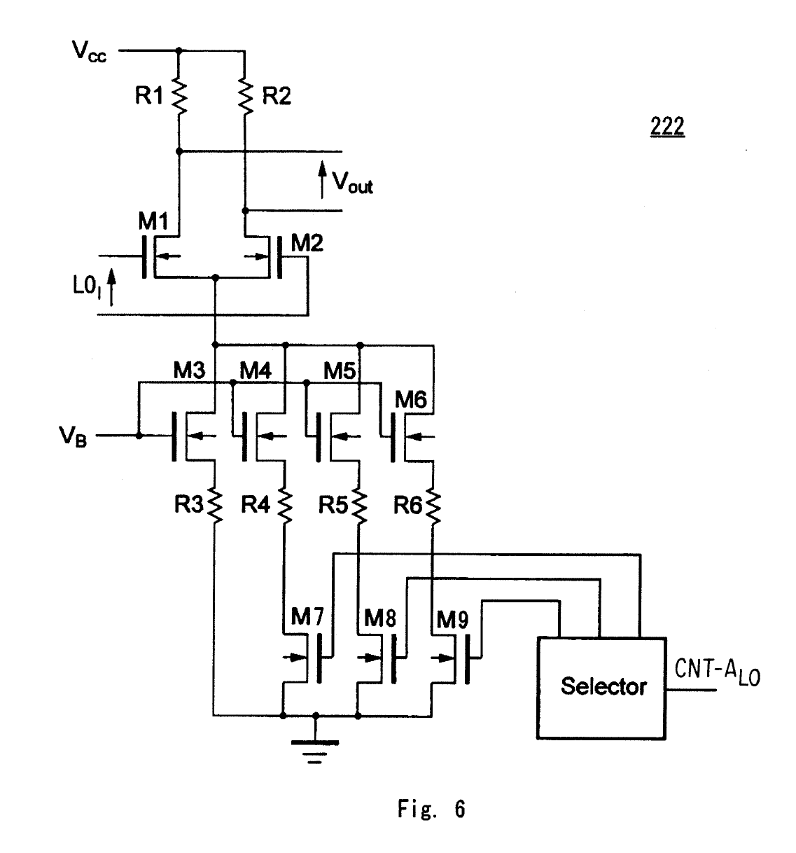

FIG. 6 is a circuit diagram of a non-limiting embodiment of LO_{I}-restrictor 222 of QMOD 300. This example employs selectable fixed resistors. The LO_{Q}-restrictor 224 may employ the same structure or a different structure.

LO_{I}-restrictor 222 includes resistors R1 to R6, transistors M1 to M9, and a selector.

V_{CC} is applied to one end of each of R1 and R2. Resistance of R1 and R2 may be the same.

The other end of R1 connects to a drain of M1. A positive input of differential signal LO_{I} is input to a gate of M1.

The other end of R2 connects to a drain of M2. A negative input of differential signal LO_{I} is input to a gate of M2.

V_{OUT}, which is a voltage between the other end of R1 and the other end of R2, is an output of the LO_{I}-restrictor 222. V_{OUT} corresponds to VLO_{I}.

Drains of transistors M3-M6 are commonly connected to the sources of transistors M1 and M2. Bias voltage VB is applied to gates of transistors M3-M6. A source of transistor M3 connects to an end of R3. A source of transistor M4 connects to an end of R4. A source of transistor M5 connects to an end of R5. A source of transistor M6 connects to an end of R6.

Resistors R4-R6 may have the same resistance.

The other end of R4 connects to a drain of transistor M7. The other end of R5 connects to a drain of transistor M8. The other end of R6 connects to a drain of transistor M9. The other end of R3 and sources of M7-M9 are grounded.

The selector separately controls the gate voltages of transistors M7-M9. That is, transistors M7-M9 may operate as switches.

Variable direct current is provided to the common sources of transistors M1 and M2.

Signal CNT-A_{LO} controls the variable direct current through the selector.

The CNT-A_{LO} may be 2 bits. For example, transistors M7-M9 shut current off when CNT-A_{LO} is “00”; M7 conducts current, and M8 and the M9 shut current off when CNT-A_{LO} is “01”; M7 and M8 conduct current, and M9 shuts current off when CNT-A_{LO} is “10”; and M7-M9 each conduct current when CNT-A_{LO} is “11”.

(Embodiment of a Radio Communicator)

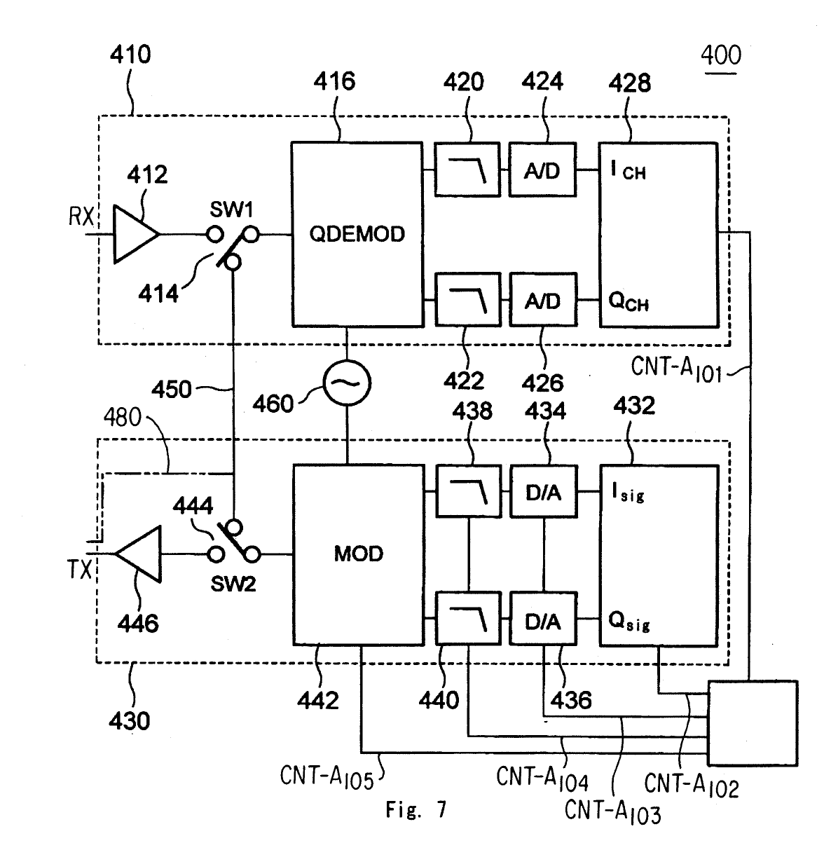

FIG. 7 is a block diagram of a non-limiting embodiment of a radio communicator 400.

The radio communicator 400 includes a receiver unit 410, a transmitter unit 430, short-circuit 450, a local oscillator 460, and an adjuster 470.

The receiver unit 410 includes a low noise amplifier (LNA) 412, a switch SW1 414, a quadrature demodulator (QDEMOD) 416, low pass filters (LPFs) 420 and 422, analog-digital converters (ADCs) 424 and 426, and a reception digital processor 428.

LNA 412 amplifies a signal RX received by an antenna (not shown).

SW1 414 selectively provides an output of the LNA 412 or a signal from the short-circuit 450 to the QDEMOD 416.

QDEMOD 416 demodulates the input signal from SW1 414 using LO provided from the local oscillator 460, and outputs in-phase output signal I_{CH} and quadrature output signal Q_{CH}.

The LPF 420 reduces higher harmonic noise of the I_{CH}. The LPF 422 reduces higher harmonic noise of the Q_{CH}.

The ADC 424 converts I_{CH} into a digital signal, and ADC 426 converts Q_{CH} into a digital signal.

The reception digital processor 428 processes outputs of ADCs 424 and 426 into reception information. The reception digital processor 428 obtains amplitude difference between I_{CH} and Q_{CH} by adjusting the baseband signal amplitude and local signal amplitude.

The transmitter unit 430 includes a transmission digital processor 432, digital-analog converters (DACs) 434 and 436, low pass filters (LPFs) 438 and 440, a quadrature modulator (QMOD) 442, a switch SW2 444, and a power amplifier (PA) 446.

The transmission digital processor 432 generates I_{sig} and Q_{sig} as digital signals.

DAC 434 converts I_{sig} into an analog signal, and DAC 436 converts Q_{sig} into an analog signal.

LPF 438 reduces higher harmonic noise of I_{sig}, and LPF 440 reduces higher harmonic noise of Q_{sig}.

QMOD 442 modulates output signals from LPFs 438 and 440 using LO provided from the local oscillator 460, and outputs transmission signal TX. The architecture of QMOD 442 may be according to the architecture of QMOD 100, 200, or 300.

SW2 444 provides TX selectively to PA 446 or to short-circuit 450.

PA 446 amplifies TX, and the amplified TX may be emitted by the antenna.

The adjuster 470 adjusts an output amplitude of at least one of the transmission digital processor 432, the DACs 434 and 436, and the LPFs 438 and 440 through signals CNT-A_{IQ1}-CNT-A_{IQ5} output by the adjuster 470 to thereby adjust the relative amplitude between I_{sig} and Q_{sig} in baseband.

A method for adjusting the baseband signal amplitude to reduce the error in the example of radio communicator 400 is described below.

When adjusting the baseband signal amplitude, SW1 414 provides the signal from short-circuit 450 to QDEMOD 416, and the SW2 444 provides TX to the short-circuit 450. That is, short-circuit 450 conducts I_{sig} and Q_{sig} from the transmission digital processor 432 to the reception digital processor 428 through QMOD 442 and QDEMOD 416.

In an alternative embodiment, a directional coupler 480 may be used. If directional coupler 480 is used for adjustment, SW2 444 provides TX not to the short-circuit 450, but to PA 446 because directional coupler 480 provides the out put of PA 446 to short-circuit 450. SW1 414 provides the signal from short-circuit 450 to QDEMOD 416.

Such methods for adjusting the baseband signal amplitude may be executed when power is applied to the radio communicator 400.

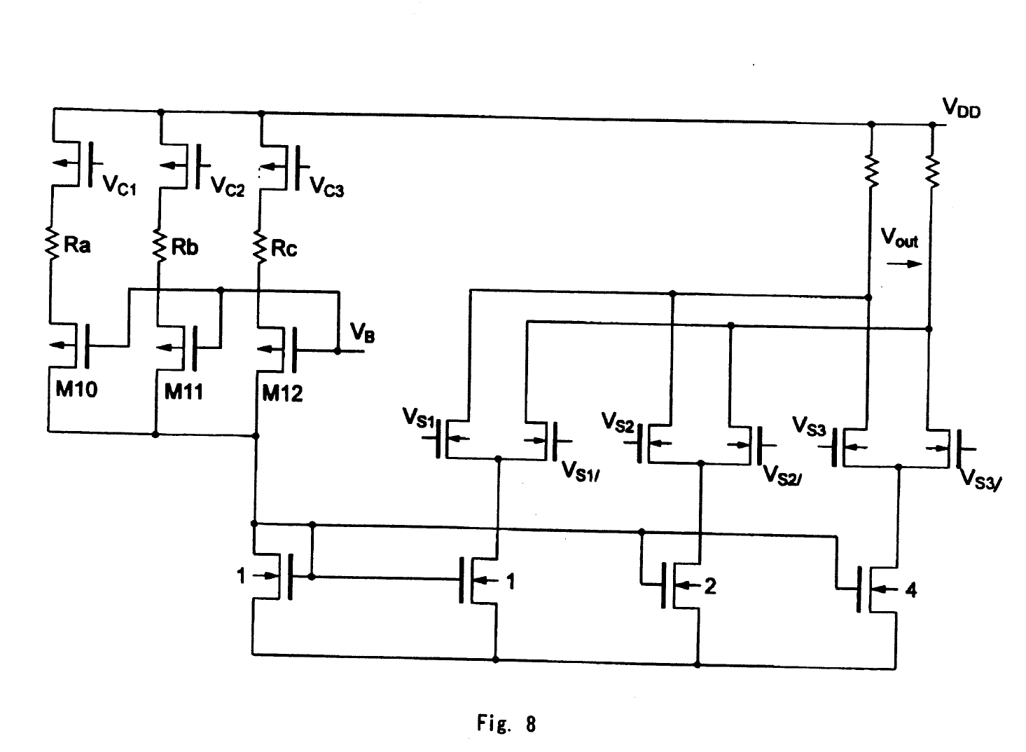

FIG. 8 is a circuit diagram of a non-limiting embodiment of a reference current generator for adjusting amplitude of the digital I_{sig} and the digital Q_{sig} generated by the transmission digital processor 432.

In FIG. 8, V_{C1}-V_{C3} are control signals to set up reference currents for DACs 434 and 436. V_{C1}-V_{C3} determine conduction or shutoff of currents to transistors M10-M12, respectively.

A sum of the currents through transistors M10-M12 can be used as the reference current. That is, the reference signal can be controlled by V_{C1}-V_{C3}. Furthermore, the output amplitude of the DAC can be calibrated.

Such a reference current generator can be used for calibrating an output amplitude of LPFs 438 and 440.

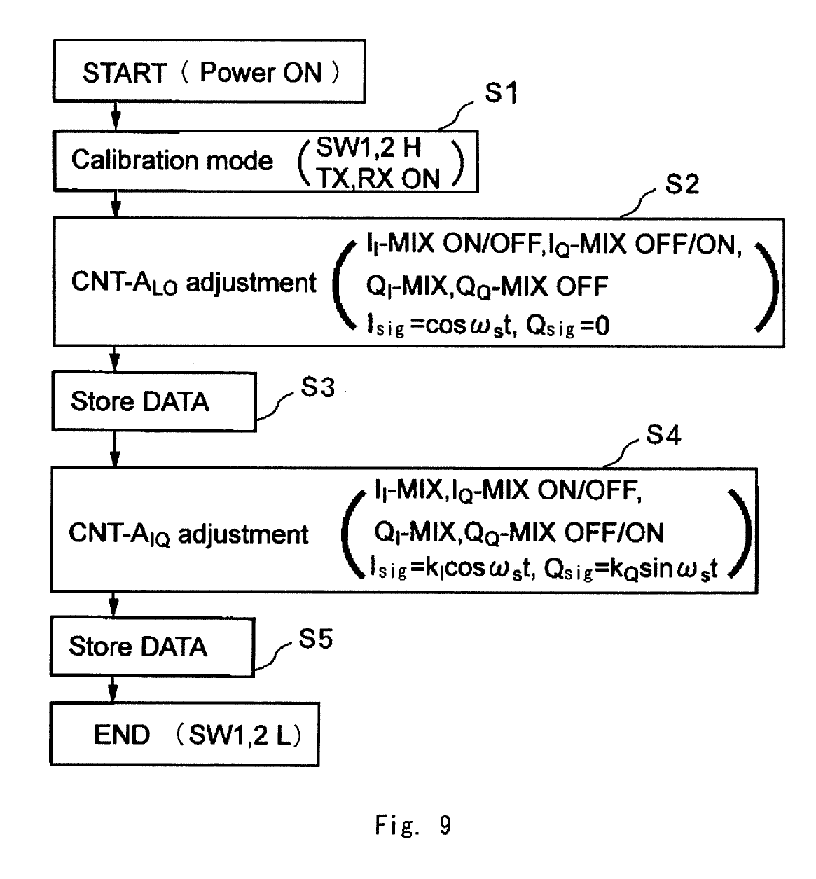

FIG. 9 is a flowchart of an embodiment of a method for adjusting the relative amplitude between I_{sig} and Q_{sig} to correct an amplitude error between OC and OD in the radio communicator 400.

In this embodiment, the adjustment is executed following the application of power to the radio communicator 400 (step S1). During the adjustment, the radio communicator 400 operates in calibration mode. Calibration mode may take place during a time when the radio communicator 400 is configured not to communicate with other radio communicators, during a time just before the radio communicator 400 is configured to communicate with other radio communicators, or during another time period.

Then, SW1 414 provides the signal from the short-circuit 450 to QDEMOD 416, and SW2 444 provides TX to the short-circuit 450. That is, the short-circuit 450 conducts I_{sig} and Q_{sig} from the transmission digital processor 432 to the reception digital processor 428 through QMOD 442 and QDEMOD 416.

If the architecture of the QMOD 442 is QMOD 300, an adjustment of amplitude of LO_{I} and LO_{Q} may be executed following step S1 (i.e., step S2). Operation of step S2 is described below.

I_{sig} is provided as a single tone signal. A frequency of the single tone signal may be within the base band, and an amplitude of I_{sig} may be predetermined.

The single tone signal may be a direct current signal having an amplitude that is significantly larger than a direct current offset of the I_{sig}.

Q_{sig} is provided as a zero-signal.

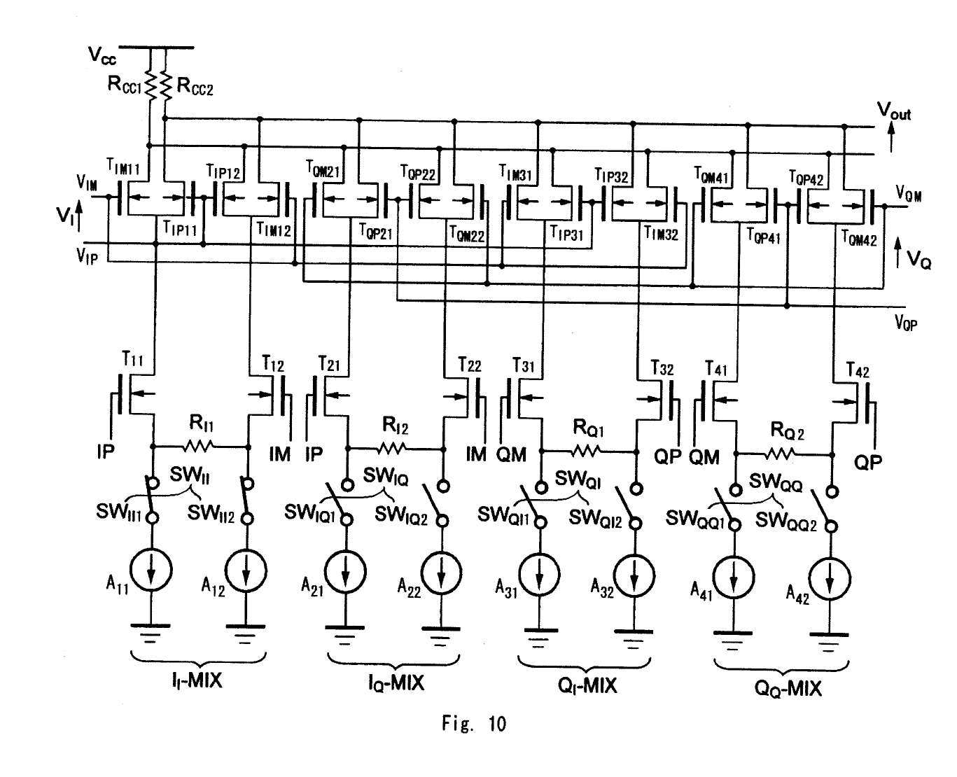

The I_{I}-mixer 250 is operated to obtain the amplitude of LO_{I}, but the I_{Q}-mixer 260 is halted. FIG. 10 is a circuit diagram of an embodiment of part 210 of QMOD 200 in FIG. 3 in this situation. In this situation, only SW_{II} is turned on, and other switches are turned off.

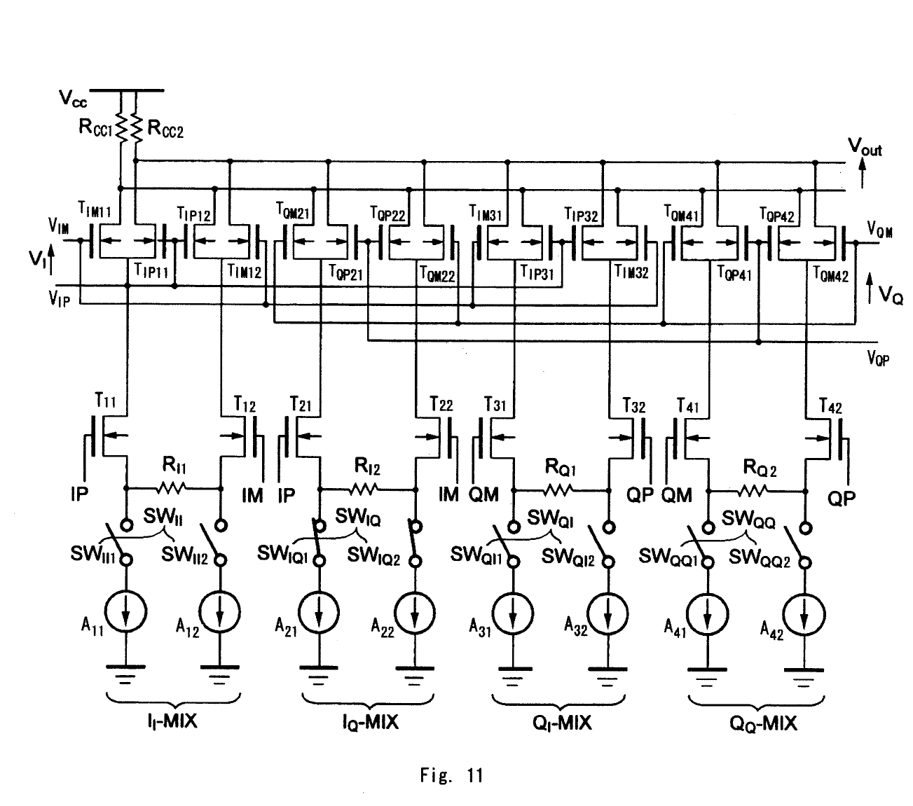

Then, the QMOD outputs RF_{II}, which is a result of mixing the I_{sig} with LO_{I}. The output is sampled and stored in a memory (not shown). After storing the output, I_{Q}-mixer 260 is operated to obtain the amplitude of LO_{Q}, but the I_{I}-mixer 250 is halted. FIG. 11 is a circuit diagram of an embodiment of part 210 of QMOD 200 in FIG. 3 in this situation. In this situation, only SW_{IQ} is turned on, and other switches are turned off.

Then, the QMOD outputs RF_{IQ}, which is a result of mixing the I_{sig} with LO_{Q}.

The output is sampled and stored in memory with the stored value of RF_{II} described above.

Because I_{sig} is common, the amplitude difference between LO_{I} and LO_{Q} can be obtained from the stored data in the memory. That is, the amplitude difference may be adjusted based on the stored values of RF_{II} and RF_{IQ}.

LO_{I}-restrictor 222 and LO_{Q}-restrictor 224 are adjusted to cancel the amplitude difference between the LO_{I} and the LO_{Q}, according to the stored data in the memory.

After the adjustment, sampling of RF_{II} and RF_{IQ} may be executed again to confirm the validity, and further adjustment may be repeated as necessary.

The adjusted gains of LO_{I}-restrictor 222 and LO_{Q}-restrictor 224 are stored in the memory (step S3).

An adjustment of relative amplitude difference between the I_{sig} and the Q_{sig} is executed (step S4), as described below.

I_{sig} is provided to I_{I}-mixer 250 and I_{Q}-mixer 260 as a single tone signal. A frequency of the single tone signal may be within the base band, and an amplitude of the I_{sig} may be predetermined. The single tone signal may be a direct current signal having an amplitude that is significantly larger than a direct current offset of the I_{sig}.

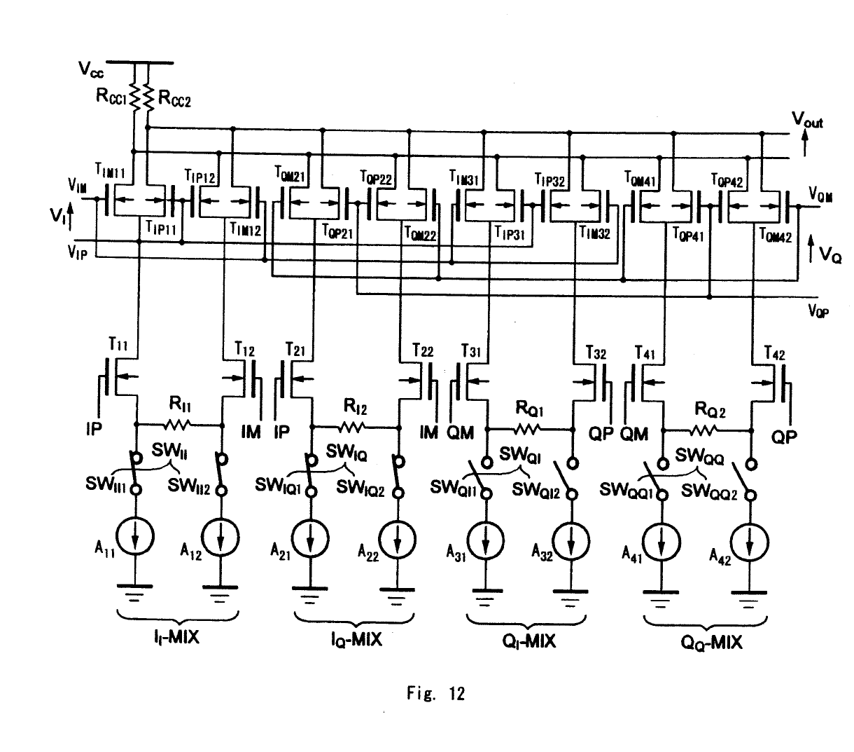

I_{I}-mixer 250 and I_{Q}-mixer 260 are operated to obtain the amplitude of I_{sig}, but Q_{I}-mixer 270 and Q_{Q}-mixer 280 are halted. FIG. 12 illustrates a circuit diagram of an embodiment of a part 210 of QMOD 200 in FIG. 3 in this situation. In this situation, SW_{II} and SW_{IQ} are turned on, and SW_{QI} and SW_{QQ} are turned off.

Then, subtracter 290 outputs S(t), which is equal to RF_{I}_{_{—}}_{Q+I} output from adder 230. The output is sampled and stored in memory (not shown).

After storing the output, Q_{sig} is provided to the Q_{I}-mixer 270 and the Q_{Q}-mixer 280 as a single tone signal. A frequency of the single tone signal may be within the base band, and an amplitude of Q_{sig} may be predetermined. The single tone signal may be a direct current signal having an amplitude that is significantly larger than a direct current offset of the Q_{sig}.

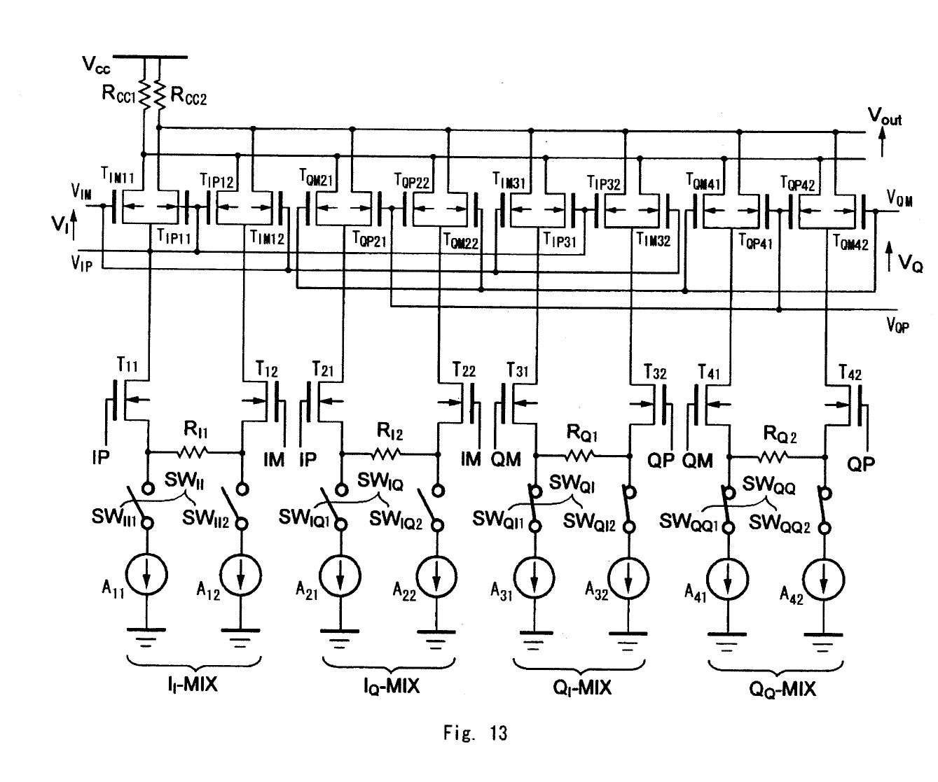

Q_{I}-mixer 270 and Q_{Q}-mixer 280 are operated to obtain the amplitude of Q_{sig}, but I_{I}-mixer 250 and I_{Q}-mixer 260 are halted. FIG. 13 is a circuit diagram of an embodiment of part 210 of QMOD 200 in FIG. 3 in this situation. In this situation, SW_{QI} and SW_{QQ} are turned on, and SW_{II} and SW_{IQ} are turned off.

Then, subtracter 290 outputs S(t), which is equal to the RF_{Q}_{_{—}}_{Q-I} output from subtracter 240. The output is sampled and stored in the memory with the stored value of RF_{I}_{_{—}}_{Q+I} described above.

Because I_{sig} and Q_{sig} may be predetermined and the amplitudes of the LO_{I} and the LO_{Q} are adjusted in order to be the same, the amplitude difference between the I_{sig} component and the Q_{sig} component in S(t) can be obtained based on the stored data in the memory.

K, which is a gain of VGA 210, is adjusted in order to cancel the amplitude difference between the I_{sig} component and the Q_{sig} component, based on the stored data in the memory.

After the adjustment, the sampling of the RF_{I}_{_{—}}_{Q+I} and the RF_{Q}_{_{—}}_{Q-I} may be executed again to confirm the validity, and the adjustment may be repeated as necessary.

The adjusted gain K of the VGA 210 is stored in the memory (step S5).

Then, SW1 414 provides the output of LNA 412 to QDEMOD 416, and SW2 444 provides TX to PA 446. That is, the calibration mode is finished, and the radio communicator 400 is ready to communicate.

Numerous modifications and variations of the present invention are possible in light of the above teachings. It is therefore to be understood that within the scope of the appended claims, the invention may be practiced otherwise than as specifically described herein.

1. A quadrature modulator for generating a transmission signal, the quadrature modulator comprising:
an orthogonal signal generator configured to generate a first local signal and a second local signal orthogonal to the first local signal;
a mix-adder configured to generate a first RF signal based on a first baseband signal, the first local signal, and the second local signal;
a mix-subtracter configured to generate a second RF signal based on a second baseband signal, the first local signal, and the second local signal;
an output subtracter configured to determine a difference between the first RF signal and the second RF signal and generate the transmission signal based on the difference; and
an amplitude adjuster configured to adjust an amplitude of the first baseband signal before feeding the first baseband signal to the mix-adder or adjust an amplitude of the second baseband signal before feeding the second baseband signal to the mix-subtracter.

2. The quadrature modulator of claim 1, wherein:
the mix-adder includes an adder and a first mixer,
the adder is configured to produce a sum of the first local signal and the second local signal, and
the first mixer is configured to mix the first baseband signal with the sum of the first local signal and the second local signal to generate the first RF signal; and
the mix-subtracter includes a subtracter and a second mixer,
the subtracter is configured to subtract the first local signal from the second local signal to produce a difference between the first local signal and the second local signal, and
the second mixer is configured to mix the second baseband signal with the difference between the first local signal and the second local signal to generate the second RF signal.

3. The quadrature modulator of claim 1, wherein
the mix-adder includes a first mixer, a second mixer, and an adder,
the first mixer is configured to mix the first baseband signal with the first local signal,
the second mixer is configured to mix the first baseband signal with the second local signal, and
the adder is configured to add the outputs of the first mixer and the second mixer to generate the first RF signal; and
the mix-subtracter includes a third mixer, a fourth mixer, and a subtracter,
the third mixer is configured to mix the second baseband signal with the first local signal,
the fourth mixer is configured to mix the second baseband signal with the second local signal, and
the subtracter is configured to generate a difference between the outputs of the third mixer and the fourth mixer as the second RF signal.

4. The quadrature modulator of claim 1, further comprising:
a local amplitude adjuster configured to adjust the first local signal before feeding the first local signal to the mix-adder and the mix-subtracter, or adjust the second local signal before feeding the second local signal to the mix-adder and the mix-subtracter.

5. A radio communicator, comprising:
a local oscillator configured to generate a source local signal;
a transmission signal processor configured to generate a first baseband signal and a second baseband signal;
an orthogonal signal generator configured to generate a first local signal and a second local signal from the source local signal, the second local signal being orthogonal to the first local signal;
a mix-adder configured to generate a first RF signal based on the first baseband signal, the first local signal, and the second local signal;
a mix-subtracter configured to generate a second RF signal based on the second baseband signal, the first local signal, and the second local signal;
an output subtracter configured to determine a difference between the first RF signal and the second RF signal and to generate the transmission signal based on the difference; and
an amplitude adjuster configured to adjust an amplitude of the first baseband signal before feeding the first baseband signal to the mix-adder, or adjust an amplitude of the second baseband signal before feeding the second baseband signal to the mix-subtracter.

6. The radio communicator of claim 5, further comprising:
a quadrature demodulator configured to demodulate the transmission signal using the source local signal; and
a signal processor configured to obtain an amplitude difference between components of a demodulated first baseband signal and a demodulated second baseband signal that are demodulated from the transmission signal,
wherein the amplitude adjuster is further configured to adjust the amplitude of the first baseband signal and the second baseband signal based on the amplitude difference obtained by the signal processor.

7. A vector correction method for canceling an amplitude difference in a transmission signal, the method comprising steps of:
generating a source local signal;
generating a first baseband signal and a second baseband signal;
generating a first local signal and a second local signal from the source local signal, the second local signal being orthogonal to the first local signal;
generating, in a mix-adder, a first RF signal based on the first baseband signal, the first local signal, and the second local signal;
generating, in a mix-subtracter, a second RF signal based on the second baseband signal, the first local signal, and the second local signal;
subtracting one of the first RF signal or the second RF signal from the other to generate the transmission signal;
demodulating the first baseband signal and the second baseband signal from the transmission signal;
configuring one of the mix-adder and the mix-subtracter as a halted mixer having a halted operation and the other one of the mix-adder and the mix-subtracter as an operating mixer;
providing the first baseband signal to the operating mixer and storing components of the first baseband signal and the second baseband signal as first storing data;
reconfiguring the halted mixer as a newly operating mixer and the operating mixer as a newly halted mixer, and providing the second baseband signal to the newly operating mixer and storing components of the first baseband signal and the second baseband signal as second storing data; and
adjusting the amplitude adjuster to cancel the amplitude difference between the components represented by the first storing data and the second storing data.

8. The method of claim 7, further comprising steps of:
adjusting the first local signal before feeding the first local signal to the mix-adder and the mix-subtracter, or adjusting the second local signal before feeding the second local signal to the mix-adder and the mix-subtracter;
mixing, in a first mixer, the first baseband signal with the first local signal to produce a first mixed signal;
mixing, in a second mixer, the first baseband signal with the second local signal to produce a second mixed signal;
adding the first mixed signal and the second mixed signal to produce the first RF signal;
mixing, in a third mixer, the second baseband signal with the first local signal to produce a third mixed signal;
mixing, in a fourth mixer, the second baseband signal with the second local signal to produce a fourth mixed signal;
generating a difference between the third mixed signal and the fourth mixed signal as the second RF signal;
configuring one of the first mixer and the second mixer as a halted mixer having a halted operation and the other of the first mixer and the second mixer as an operating mixer;
providing an actual signal as the first baseband signal and a zero signal as the second baseband signal in the mix-adder, while storing components of a demodulated first baseband signal and a second demodulated baseband signal, which are demodulated from the transmission signal, as first storing data;
reconfiguring the halted mixer as a newly operating mixer and the operating mixer as a newly halted mixer, and providing the actual signal as the first baseband signal and the zero signal as the second baseband signal in the mix-adder, while storing components of the demodulated first baseband signal and the demodulated second baseband signal as second storing data; and
adjusting the local amplitude adjuster to cancel the amplitude difference between the components represented by the first storing data and the second storing data.

9. The method of claim 7, further comprising steps of:
adjusting the first local signal before feeding the first local signal to the mix-adder and the mix-subtracter, or adjusting the second local signal before feeding the second local signal to the mix-adder and the mix-subtracter;
mixing, in a first mixer, the first baseband signal with the first local signal to produce a first mixed signal;
mixing, in a second mixer, the first baseband signal with the second local signal to produce a second mixed signal;
adding the first mixed signal and the second mixed signal to produce the first RF signal;
mixing, in a third mixer, the second baseband signal with the first local signal to produce a third mixed signal;
mixing, in a fourth mixer, the second baseband signal with the second local signal to produce a fourth mixed signal;
generating a difference between the third mixed signal and the fourth mixed signal as the second RF signal;
configuring one of the third mixer and the fourth mixer as a halted mixer having a halted operation and the other of the third mixer and the fourth mixer as an operating mixer;
providing an actual signal as the first baseband signal and a zero signal as the second baseband signal in the mix-subtracter, while storing components of a demodulated first baseband signal and a demodulated second baseband signal, which are demodulated from the transmission signal, as first storing data;
reconfiguring the halted mixer as a newly operating mixer and the operating mixer as a newly halted mixer, and providing the actual signal as the first baseband signal and the zero signal as the second baseband signal in the mix-subtracter, while storing components of the demodulated first baseband signal and the demodulated second baseband signal as second storing data; and
adjusting the local amplitude adjuster in order to cancel the amplitude difference between the components represented by the first storing data and the second storing data.

10. The method of claim 7, further comprising steps of:
adjusting the first local signal before feeding the first local signal to the mix-adder and the mix-subtracter, or adjusting the second local signal before feeding the second local signal to the mix-adder and the mix-subtracter;
mixing, in a first mixer, the first baseband signal with the first local signal to produce a first mixed signal;
mixing, in a second mixer, the first baseband signal with the second local signal to produce a second mixed signal;
adding the first mixed signal and the second mixed signal to produce the first RF signal;
mixing, in a third mixer, the second baseband signal with the first local signal to produce a third mixed signal;
mixing, in a fourth mixer, the second baseband signal with the second local signal to produce a fourth mixed signal;
generating a difference between the third mixed signal and the fourth mixed signal as the second RF signal;
configuring one of the first mixer and the second mixer as a halted mixer having a halted operation and the other of the first mixer and the second mixer as an operating mixer;
providing a zero signal as the first baseband signal and an actual signal as the second baseband signal the mix-adder, while storing components of a demodulated first baseband signal and a demodulated second baseband signal, which are demodulated from the transmission signal, as first storing data;
reconfiguring the halted mixer as a newly operating mixer and the operating mixer as a newly halted mixer, and providing the zero signal as the first baseband signal and the actual signal as the second baseband signal in the mix-adder, while storing components of the demodulated first baseband signal and the demodulated second baseband signal as second storing data; and
adjusting the local amplitude adjuster to cancel the amplitude difference between the components represented by the first storing data and the second storing data.

11. The method of claim 7, further comprising steps of:
adjusting the first local signal before feeding the first local signal to the mix-adder and the mix-subtracter, or adjusting the second local signal before feeding the second local signal to the mix-adder and the mix-subtracter;
mixing, in a first mixer, the first baseband signal with the first local signal to produce a first mixed signal;
mixing, in a second mixer, the first baseband signal with the second local signal to produce a second mixed signal;
adding the first mixed signal and the second mixed signal to produce the first RF signal;
mixing, in a third mixer, the second baseband signal with the first local signal to produce a third mixed signal;
mixing, in a fourth mixer, the second baseband signal with the second local signal to produce a fourth mixed signal;
generating a difference between the third mixed signal and the fourth mixed signal as the second RF signal;
configuring one of the third mixer and the fourth mixer as a halted mixer having a halted operation and the other of the third mixer and the fourth mixer as an operating mixer;
providing a zero signal as the first baseband signal and an actual signal as the second baseband signal in the mix-subtracter, while storing components of a demodulated first baseband signal and a demodulated second baseband signal, which are demodulated from the transmission signal, as first storing data;
reconfiguring the halted mixer as a newly operating mixer and the operating mixer as a newly halted mixer, and providing the zero signal as the first baseband signal and the actual signal as the second baseband signal in the mix-subtracter, while storing components of the demodulated first baseband signal and the demodulated second baseband signal as second storing data; and
adjusting the local amplitude adjuster to cancel the amplitude difference between the components represented by the first storing data and the second storing data.
